(19) United States
(12) Patent Application Publication
(10) Pub. No.: US 2007/0235814 A1
(43) Pub. Date: Oct. 11, 2007

(54) GaN-based semiconductor light-emitting device and method of manufacturing the same

(75) Inventors: Jae-hee Cho, Yongin-si (KR); Joon-seop Kwak, Yongin-si (KR)

Correspondence Address: BUCHANAN, INGERSOLL & ROONEY PC, POST OFFICE BOX 1404, ALEXANDRIA, VA, 22313-1404, US

(73) Assignee: Samsung Electro-mechanics Co., Ltd., Suwon-si (KR)

(21) Appl. No.: 11/654,602

(22) Filed: Jan. 18, 2007

(30) Foreign Application Priority Data
Apr. 5, 2006 (KR) 10-2006-0030992

(51) Int. Cl. H01L 29/94; H01L 29/76

(52) U.S. Cl. 257/369

(57) ABSTRACT

A GaN-based semiconductor light-emitting device is provided having an improved structure in which the optical output and luminous efficiency are improved. The GaN-based semiconductor light-emitting device includes an n-electrode, a p-electrode, and an n-type semiconductor layer, an active layer and a p-type semiconductor layer, which are disposed between the n-electrode and the p-electrode, wherein the p-electrode includes a first electrode layer formed of Zn or a Zn-based alloy on the p-type semiconductor layer, a second electrode layer formed of Ag or an Ag-based alloy on the first electrode layer, and a third electrode layer formed of a transparent conductive oxide on the second electrode layer.

### CROSS-REFERENCE TO RELATED PATENT APPLICATION

This application claims the benefit of Korean Patent Application No. 10-2006-0030992, filed on Apr. 5, 2006, in the Korean Intellectual Property Office, the disclosure of which is incorporated herein in its entirety by reference.

### BACKGROUND OF THE DISCLOSURE

1. Field of the Disclosure

The present disclosure relates to a semiconductor light-emitting device, and more particularly, to a GaN-based semiconductor light-emitting device having an improved structure in which the optical output and the luminous efficiency are improved, and a method of manufacturing the same.

2. Description of the Related Art

Laser light produced by a semiconductor laser diode such as a compound semiconductor light-emitting device, for example, a light emitting diode (LED) or a laser diode (LD) in which an electrical signal is transformed into light using compound semiconductor characteristics, has been applied in fields such as optical communication, multiple communication, and space communication. Also, semiconductor lasers have been widely used as light sources for data transmission and data recording and reading in communication areas such as optical communication and in devices such as compact disk players (CDP) and digital versatile disk players (DVDP).

Compound semiconductor light-emitting devices are classified into top-emitting light emitting diodes (TLED) and flip-chip light emitting diodes (FCLED) according to the direction in which the light is emitted.

In FCLEDs, light generated in an active layer is reflected by a reflective electrode formed on a p-type compound semiconductor layer and the reflected light is transmitted through a substrate. On the contrary, TLEDs have a structure in which light is transmitted through a p-electrode that forms a p-type compound semiconductor layer and establishes an ohmic contact. Here, the p-electrode of a TLED usually has a structure in which an Ni layer and an Au layer are sequentially stacked on a p-type compound semiconductor layer. A more detailed description of the Ni/Au stack structure of the p-electrode is disclosed in U.S. Pat. No. 5,877,558. However, since the p-electrode having the Ni/Au stack structure is semi-transparent, a TLED having such a p-electrode has a low optical efficiency and low brightness. Accordingly, to address the problems, a study with respect to an electrode material and an electrode structure each having a low contact resistance and a high light transmissivity has been conducted.

### SUMMARY OF THE DISCLOSURE

The present invention may provide a GaN-based semiconductor light-emitting device having an improved structure in which the optical output and the luminous efficiency are improved and a method of manufacturing the same.

According to an aspect of the present invention, there may be provided a GaN-based semiconductor light-emitting device, the device including: an n-electrode; a p-electrode; and an n-type semiconductor layer, an active layer and a p-type semiconductor layer, which are disposed between the n-electrode and the p-electrode, wherein the p-electrode includes: a first electrode layer formed of Zn or a Zn-based alloy on the p-type semiconductor layer; a second electrode layer formed of Ag or an Ag-based alloy on the first electrode layer; and a third electrode layer formed of a transparent conductive oxide on the second electrode layer.

The Zn-based alloy may include Zn and at least one metal selected from the group consisting of Ag, Mg, Sc, Hf, Zr, Te, Se, Ta, W, Nb, Cu, Si, Ni, Co, Mo, Cr, Mn, Hg, Pr, and La. The Zn-based alloy may be an alloy selected from the group consisting of Zn—Ni, Zn—Mg, and Zn—Cu. The Ag-based alloy may include Ag and at least one metal selected from the group consisting of Zn, Mg, Sc, Hf, Zr, Te, Se, Ta, W, Nb, Cu, Si, Ni, Co, Mo, Cr, Mn, Hg, Pr, and La. The Ag-based alloy may be one alloy selected from the group consisting of Ag—Cu, Ag—Ni, Ag—Zn, and Ag—Mg. The transparent conductive oxide may be an oxide of at least one metal selected from the group consisting of In, Sn, Zn, Ga, Cd, Mg, Be, Ag, Mo, V, Cu, Ir, Rh, Ru, W, Co, Ni, Mn, and La. The transparent conductive oxide may be indium tin oxide (ITO) or zinc oxide (ZnO).

Each of the first and second electrode layers may be formed to a thickness of approximately 0.1 nm to 500 nm. The third electrode layer may be formed to a thickness of approximately 10 nm to 1000 nm.

According to another aspect of the present invention, there is provided a method of manufacturing a GaN-based semiconductor light-emitting device, the method including: sequentially forming an n-type semiconductor layer, an active layer and a p-type semiconductor layer on a substrate; forming an n-electrode on the n-type semiconductor layer; and forming a p-electrode on the p-type semiconductor layer, wherein the forming of the p-electrode includes: forming a first electrode layer using Zn or a Zn-based alloy on the p-type semiconductor layer; forming a second electrode layer using Ag or an Ag-based alloy on the first electrode layer; forming a third electrode layer using a transparent conductive oxide on the second electrode layer; and annealing the first, second and third electrode layers.

The annealing may be performed at a temperature of approximately 200° C. to 700° C. for approximately 10 seconds to 2 hours. The annealing may be performed in a gas atmosphere including oxygen. The gas atmosphere may further include at least one gas selected from the group consisting of nitrogen, argon, helium, oxygen, and air. Each of the first, second and third electrode layers may be formed using an e-beam and a thermal evaporator.

According to the present invention, the GaN-based semiconductor light-emitting device including the p-electrode having low contact resistance and high light transmissivity can be manufactured. Thus, current-voltage characteristics and light transmissivity in the p-electrode are improved so that the GaN-based semiconductor light-emitting device having an improved optical output and luminous efficiency compared to prior art can be obtained.

### BRIEF DESCRIPTION OF THE DRAWINGS

The above and other features and advantages of the present invention will be described in detailed exemplary embodiments thereof with reference to the attached drawings in which:

FIG. 1 is a cross-sectional view of an exemplary GaN-based semiconductor light-emitting device according to an embodiment of the invention;

FIG. 2 is an enlarged view of the p-electrode of the GaN-based semiconductor light-emitting device of FIG. 1;

FIG. 3 is a transmission electron microscope (TEM) photo of a p-electrode manufactured in a ZnNi(2.5 nm)/Ag(2.5 nm)/ITO(200 nm) stack structure;

FIG. 4 is a graph of voltage versus current with respect to the p-electrode manufactured in the ZnNi(2.5 nm)/Ag(2.5 nm)/ITO(200 nm) stack structure;

FIG. 5 is a graph of voltage versus current of a GaN-based semiconductor light-emitting device having the p-electrode manufactured in the ZnNi(2.5 nm)/Ag(2.5 nm)/ITO(200 nm) stack structure; and

FIGS. 6A through 6D are cross-sectional views illustrating a method of manufacturing a GaN-based semiconductor light-emitting device according to an embodiment of the present invention.

### DETAILED DESCRIPTION OF PREFERRED EMBODIMENTS

The present invention will now be described more fully with reference to the accompanying drawings, in which exemplary embodiments of the invention are shown. In the drawings, the thicknesses of layers and regions are exaggerated for clarity.

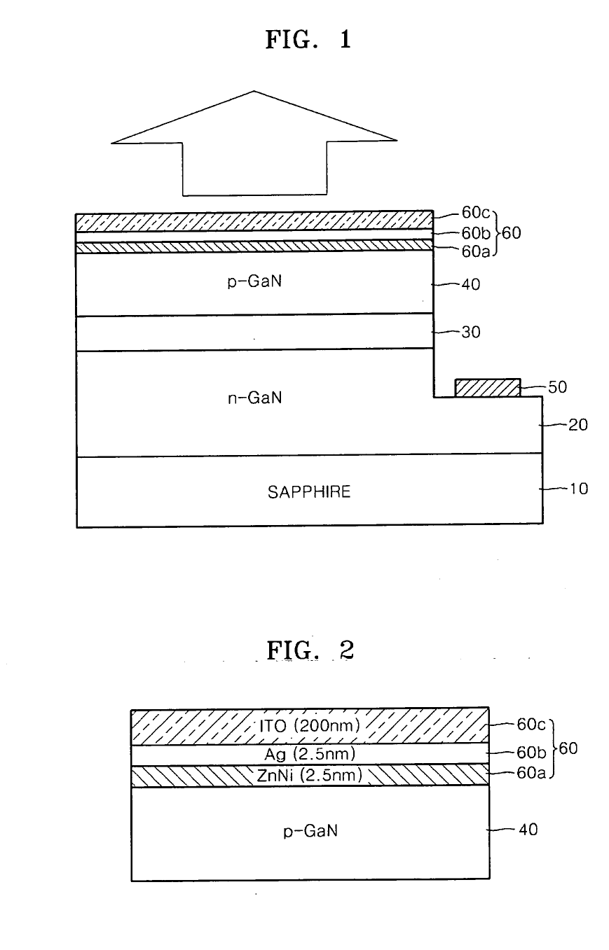

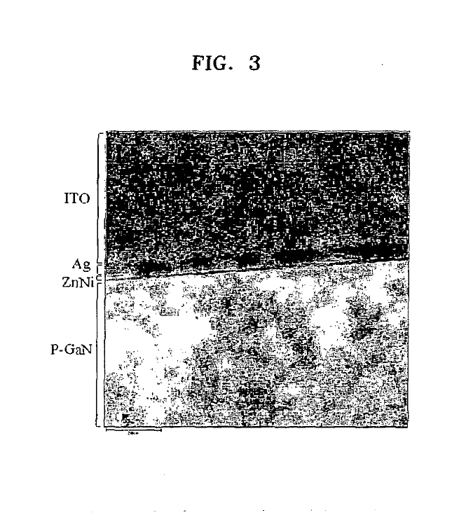

FIG. 1 is a cross-sectional view of a GaN-based semiconductor light-emitting device according to an embodiment of the invention and FIG. 2 is an enlarged view of a p-electrode of the GaN-based semiconductor light-emitting device of FIG. 1.

Referring to FIGS. 1 and 2, the GaN-based semiconductor light-emitting device includes an n-electrode 50, a p-electrode 60, and an n-type semiconductor layer 20, an active layer 30 and a p-type semiconductor layer, which are disposed between the n-electrode 50 and the p-electrode 60. Specifically, the n-type semiconductor layer 20, the active layer 30 and the p-type semiconductor layer 40 are sequentially stacked on a substrate 10, a portion of the uppermost surface of the p-type semiconductor layer 40 is etched to a predetermined depth of the n-type semiconductor layer 20 and a portion of the n-type semiconductor layer 20 is exposed. The n-electrode 50 is formed on the exposed surface of the n-type semiconductor layer 20 and the p-electrode 60 is formed on the uppermost surface of the p-type semiconductor layer 40. In the GaN-based semiconductor light-emitting device having the above structure, if a predetermined voltage is applied between the n-electrode 50 and the p-electrode 60, electrons and holes are injected into the active layer 30 from the n-type semiconductor layer 20 and the p-type semiconductor layer 40, respectively, and are combined within the active layer 30 so that light can be emitted from the active layer 30.

In the present invention, the p-electrode 60 is formed in a multilayered electrode including first, second and third electrode layers 60a, 60b and 60c, which are sequentially stacked on the n-type semiconductor layer 20. The present invention is characterized by the structure of the p-electrode 60 and a material therefore. In the GaN-based semiconductor light-emitting device, the p-electrode 60 includes the first electrode layer 60a formed of Zn or a Zn-based alloy on the p-type semiconductor layer 40, the second electrode layer 60b formed of Ag or an Ag-based alloy on the first electrode layer 60a, and the third electrode layer 60c formed of a transparent conductive oxide on the second electrode layer 60b. According to the p-electrode 60 formed by a combination of the first, second and third electrode layers 60a, 60b and 60c stacked in the above order, since low contact resistance and high light transmissivity can be obtained in the p-electrode 60 according to experimental results, the optical output and the luminous efficiency of the GaN-based semiconductor light-emitting device can be improved compared to the prior art.

The Zn-based alloy includes Zn and at least one metal selected from the group consisting of Ag, Mg, Sc, Hf, Zr, Te, Se, Ta, W, Nb, Cu, Si, Ni, Co, Mo, Cr, Mn, Hg, Pr, and La. Preferably, the Zn-based alloy is an alloy selected from the group consisting of Zn—Ni, Zn—Mg, and Zn—Cu. And, the Ag-based alloy includes Ag and at least one metal selected from the group consisting of Zn, Mg, Sc, Hf, Zr, Te, Se, Ta, W, Nb, Cu, Si, Ni, Co, Mo, Cr, Mn, Hg, Pr, and La. Preferably, the Ag-based alloy is an alloy selected from the group consisting of Ag—Cu, Ag—Ni, Ag—Zn and Ag—Mg. The transparent conductive oxide is an oxide of at least one metal selected from the group consisting of In, Sn, Zn, Ga, Cd, Mg, Be, Ag, Mo, V, Cu, Ir, Rh, Ru, W, Co, Ni, Mn, and La. Preferably, the transparent conductive oxide is indium tin oxide (ITO) or zinc oxide (ZnO). Each of the first and second electrode layers 60a and 60b is formed in a thickness of approximately 0.1 nm to 500 nm. Preferably, the third electrode layer 60c is formed in a thickness of approximately 10 nm to 1000 nm.

A sapphire substrate or a freestanding GaN substrate may be used as the substrate 10. And, the n-type semiconductor layer 20 is formed of an AlInGaN-based III-V-group nitride semiconductor material and in particular, may be an n-GaN layer or n-GaN/AlGaN layer. The p-type semiconductor layer 40 is formed of a p-GaN-based III-V-group nitride semiconductor layer and in particular, may be a p-GaN layer or p-GaN/AlGaN layer.

The active layer 30 is formed of a GaN-based III-V-group nitride semiconductor layer which is InₓAl_{y}Ga_{1-x-y}N(0≦x≦1, 0≦y≦1 and 0≦x+y≦1 and in particular, may be an InGaN layer of AlGaN layer. Here, the active layer 30 may have any structure of a multi-quantum well (hereinafter, referred to as ‘MQW’) structure and a single quantum well structure. The structure of the active layer 30 does not limit a technical scope of the present invention. For example, most preferably, the active layer 30 is formed in a GaN/InGaN/GaN MQW or GaN/AlGaN/GaN MQW structure.

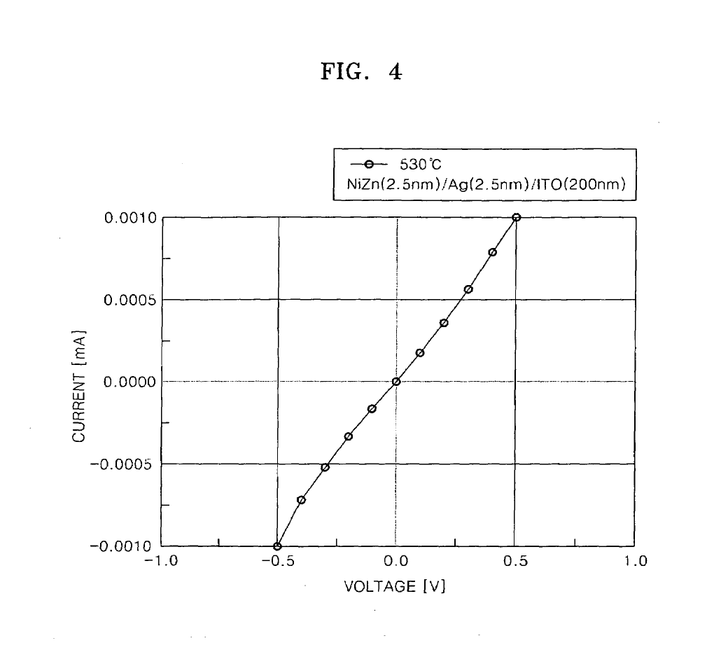

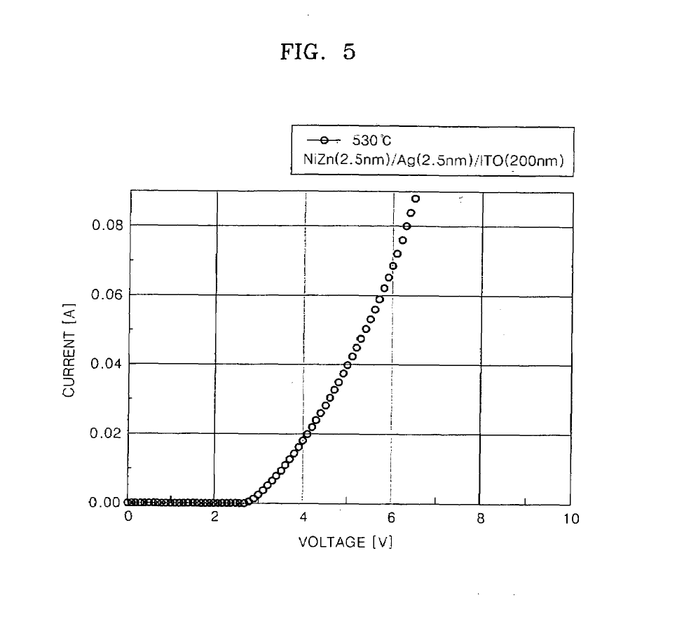

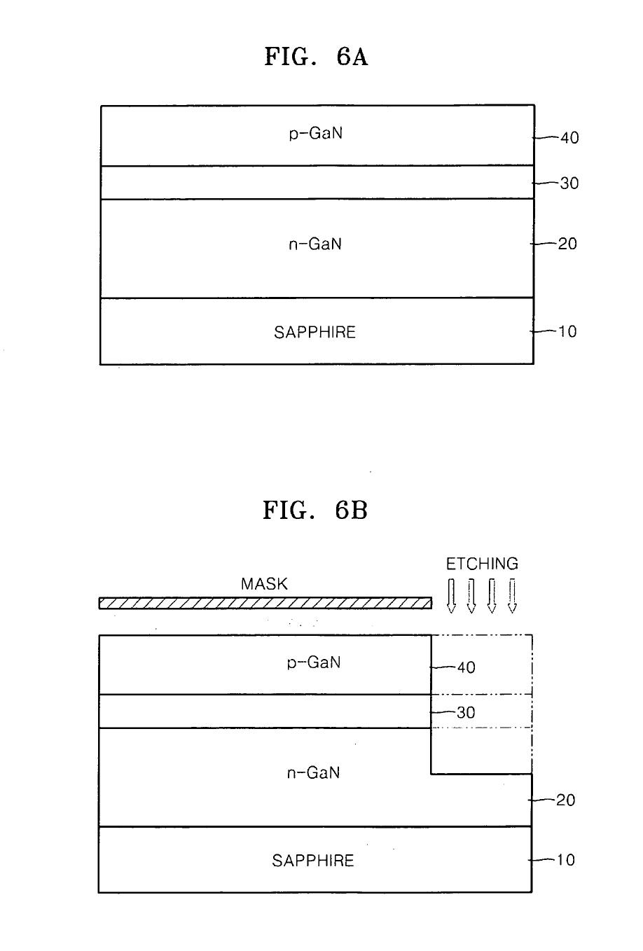

FIG. 3 is a transmission electron microscope (TEM) photo of a p-electrode manufactured in a ZnNi(2.5 nm)/Ag(2.5 nm)/ITO(200 nm) stack structure, FIG. 4 is a graph of voltage versus current with respect to the p-electrode manufactured in the ZnNi(2.5 nm)/Ag(2.5 nm)/ITO(200 nm) stack structure, and FIG. 5 is a graph of voltage versus current of a GaN-based semiconductor light-emitting device having the p-electrode manufactured in the ZnNi(2.5 nm)/Ag(2.5 nm)/ITO(200 nm) stack structure.

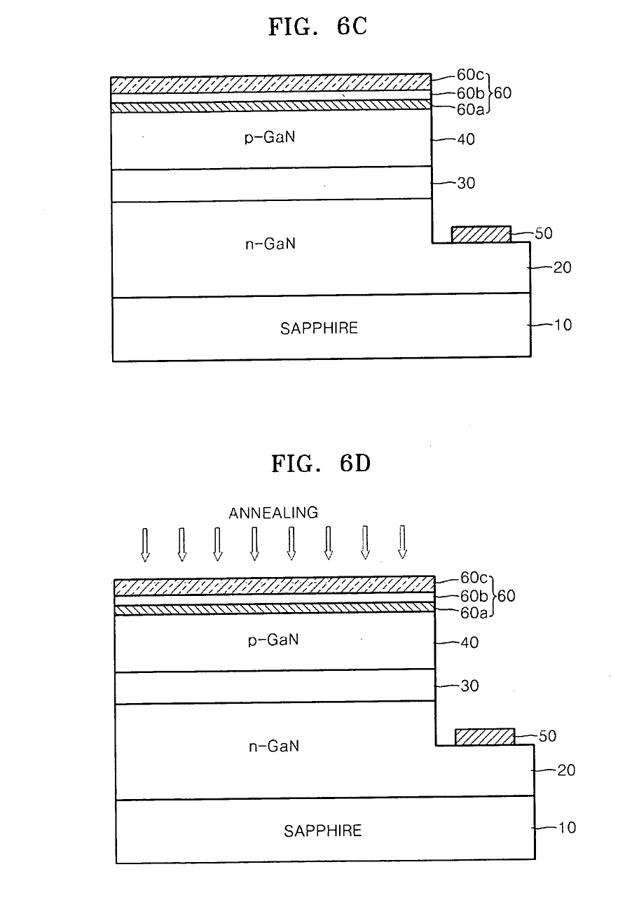

FIGS. 6A through 6D are cross-sectional views illustrating a method of manufacturing a GaN-based semiconductor light-emitting device according to an embodiment of the present invention.

Referring to FIG. 6A, an n-type semiconductor layer 20, an active layer 30 and a p-type semiconductor layer 40 are sequentially stacked on a substrate 10. Specifically, the n-type semiconductor layer 20 is formed on the previously-prepared substrate 10, for example, on a GaN or sapphire substrate by the same kind of stacking method (for example, growth of a GaN-based crystal layer on a GaN substrate) or a different kind of stacking method (for example, growth of a GaN-based crystal layer on a sapphire substrate). The n-type semiconductor layer 20 is formed of an AlInGaN-based III-V-group nitride semiconductor material and in particular, may be an n-GaN layer or n-GaN/AlGaN layer.

The active layer 30 is formed of a GaN-based III-V-group nitride semiconductor layer which is InₓAl_{y}Ga_{1-x-y}N(0≦x≦1, 0≦y≦1 and 0≦x+y≦1) and in particular, may be an InGaN layer or AlGaN layer. Here, the active layer 30 may have any one structure of a multi-quantum well (hereinafter, referred to as ‘MQW’) structure or a single quantum well structure. The structure of the active layer 30 does not limit a technical scope of the present invention. For example, most preferably, the active layer 30 is formed of a GaN/InGaN/GaN MQW or a GaN/AlGaN/GaN MQW structure.

The p-type semiconductor layer 40 is formed of a p-GaN-based III-V-group nitride semiconductor layer and in particular, may be a p-GaN layer or p-GaN/AlGaN layer.

Here, respective material layers may be formed by thin film deposition that is generally used in a semiconductor manufacturing process, for example, vapor deposition such as physical vapor deposition (PVD), chemical vapor deposition (CVD) or evaporation. These methods are widely well known and thus, a detailed description thereof is not included.

Referring to FIGS. 6B and 6C, a portion of the uppermost surface of the p-type semiconductor layer 40 is selected and is etched to a predetermined depth of the n-type semiconductor layer 20 from the selected portion and a portion of the n-type semiconductor layer 20 is exposed. Thereafter an n-electrode 50 is formed on the exposed surface of the n-type semiconductor layer 20 using a conductive material, such as Ag or Al. First, second and third electrode layers 60a, 60b and 60c are sequentially stacked on the p-type semiconductor layer 40. In this instance, the first electrode layer 60a is formed of Zn or a Zn-based alloy in a thickness of approximately 0.1 nm to 500 nm. The Zn-based alloy includes Zn and at least one metal selected from the group consisting of Ag, Mg, Sc, Hf, Zr, Te, Se, Ta, W, Nb, Cu, Si, Ni, Co, Mo, Cr, Mn, Hg, Pr and La. Preferably, the Zn-based alloy is an alloy selected from the group consisting of Zn—Ni, Zn—Mg, and Zn—Cu. The second electrode layer 60b is formed of Ag or an Ag-based alloy in a thickness of approximately 0.1 nm to 500 nm. The Ag-based alloy includes Ag and at least one metal selected from the group consisting of Zn, Mg, Sc, Hf, Zr, Te, Se, Ta, W, Nb, Cu, Si, Ni, Co, Mo, Cr, Mn, Hg, Pr, and La. Preferably, the Ag-based alloy is an alloy selected from the group consisting of Ag—Cu, Ag—Ni, Ag—Zn, and Ag—Mg. The third electrode layer 60c is formed of a transparent conductive oxide in a thickness of approximately 10 nm to 1000 nm. The transparent conductive oxide is an oxide of at least one metal selected from the group consisting of In, Sn, Zn, Ga, Cd, Mg, Be, Ag, Mo, V, Cu, Ir, Rh, Ru, W, Co, Ni, Mn, and La. Preferably, the transparent conductive oxide is indium tin oxide (ITO) or zinc oxide (ZnO). Each of the first, second and third electrode layers 60a, 60b and 60c may be formed using an e-beam and a thermal evaporator.

Referring to FIG. 6D, the first, second and third 60a, 60b and 60c are annealed at a temperature of approximately 200° C. to 700° C., preferably, at approximately 530° C., for approximately 10 seconds to 2 hours. The annealing is performed in a gaseous atmosphere including oxygen. Preferably, the gaseous atmosphere may further include at least one gas selected from the group consisting of nitrogen, argon, helium, hydrogen, and air. Through the above process, the GaN-based semiconductor light-emitting device having a low contact resistance and a high light transmissivity according to the present invention can be manufactured.

According to the present invention, the GaN-based semiconductor light-emitting device including the p-electrode having the high light transmissivity can be manufactured. Accordingly, the current-voltage characteristics and light transmissivity in the p-electrode are improved such that a GaN-based semiconductor light-emitting device is obtained having an improved optical output and luminous efficiency compared to prior arts.

While the present invention has been particularly shown and described with reference to exemplary embodiments thereof, it will be understood by those of ordinary skill in the art that various changes in form and details may be-made therein without departing from the spirit and scope of the present invention as defined by the following claims.

What is claimed is:

1. A GaN-based semiconductor light-emitting device comprising:
an n-electrode;
a p-electrode; and
an n-type semiconductor layer, an active layer, and a p-type semiconductor layer which are disposed between the n-electrode and the p-electrode,
wherein the p-electrode comprises:
a first electrode layer formed of Zn or a Zn-based alloy on the p-type semiconductor layer;
a second electrode layer formed of Ag or an Ag-based alloy on the first electrode layer; and
a third electrode layer formed of a transparent conductive oxide on the second electrode layer.

2. The device of claim 1, wherein the Zn-based alloy comprises Zn and at least one metal selected from the group consisting of Ag, Mg, Sc, Hf, Zr, Te, Se, Ta, W, Nb, Cu, Si, Ni, Co, Mo, Cr, Mn, Hg, Pr, and La.

3. The device of claim 2, wherein the Zn-based alloy is an alloy selected from the group consisting of Zn—Ni, Zn—Mg, and Zn—Cu.

4. The device of claim 1, wherein the Ag-based alloy comprises Ag and at least one metal selected from the group consisting of Zn, Mg, Sc, Hf, Zr, Te, Se, Ta, W, Nb, Cu, Si, Ni, Co, Mo, Cr, Mn, Hg, Pr, and La.

5. The device of claim 4, wherein the Ag-based alloy is an alloy selected from the group consisting of Ag—Cu, Ag—Ni, Ag—Zn, and Ag—Mg.

6. The device of claim 1, wherein the transparent conductive oxide is an oxide of at least one metal selected from the group consisting of In, Sn, Zn, Ga, Cd, Mg, Be, Ag, Mo, V, Cu, Ir, Rh, Ru, W, Co, Ni, Mn, and La.

7. The device of claim 6, wherein the transparent conductive oxide is indium tin oxide (ITO) or zinc oxide (ZnO).

8. The device of claim 1, wherein the first electrode layer is formed in a thickness of approximately 0.1 nm to 500 nm.

9. The device of claim 1, wherein the second electrode layer is formed in a thickness of approximately 0.1 nm to 500 nm.

10. The device of claim 1, wherein the third electrode layer is formed in a thickness of approximately 10 nm to 1000 nm.

11. A method of manufacturing a GaN-based semiconductor light-emitting device comprising:
sequentially forming an n-type semiconductor layer, an active layer and a p-type semiconductor layer on a substrate;
forming an n-electrode on the n-type semiconductor layer; and
forming a p-elecitrnde on the p-type semiconductor layer,
wherein the forming of the p-electrode comprises:
forming a first electrode layer using Zn or a Zn-based alloy on the p-type semiconductor layer;
forming a second electrode layer using Ag or an Ag-based alloy on the first electrode layer;
forming a third electrode layer using a transparent conductive oxide on the second electrode layer; and
annealing the first, second and third electrode layers.

12. The method of claim 11, wherein the annealing is performed at a temperature of approximately 200° C. to 700° C.

13. The method of claim 12, wherein the annealing is performed for approximately 10 seconds to 2 hours.

14. The method of claim 12, wherein the annealing is performed in a gaseous atmosphere including oxygen.

15. The method of claim 14, wherein the gaseous atmosphere further comprises at least one gas selected from the group consisting of nitrogen, argon, helium, oxygen, and air.

16. The method of claim 11, wherein each of the first, second and third electrode layers are formed using an e-beam and thermal evaporator.

17. The method of claim 11, wherein the Zn-based alloy comprises Zn and at least one metal selected from the group consisting of Ag, Mg, Sc, Hf, Zr, Te, Se, Ta, W, Nb, Cu, Si, Ni, Co, Mo, Cr, Mn, Hg, Pr, and La.

18. The method of claim 17, wherein the Zn-based alloy is an alloy selected from the group consisting of Zn—Ni, Zn-Ma, and Zn—Cu.

19. The method of claim 11, wherein the Ag-based alloy comprises Ag and at least one metal selected from the group consisting of Zn, Mg, Sc, Hf, Zr, Te, Se, Ta, W, Nb, Cu, Si, Ni, Co, Mo, Cr, Mn, Hg, Pr, and La.

20. The method of claim 19, the Ag-based alloy is an alloy selected from the group consisting of Ag—Cu, Ag—Ni, Ag—Zn, and Ag—Mg.

21. The method of claim 11, wherein the transparent conductive oxide is an oxide of at least one metal selected from the group consisting of In, Sn, Zn, Ga, Cd, Mg, Be, Ag, Mo, V, Cu, Ir, Rh, Ru, W, Co, Ni, Mo, and La.

22. The method of claim 21, wherein the transparent conductive oxide is indium tin oxide (ITO) or zinc oxide (ZnO).

23. The method of claim 11, wherein the first electrode layer is formed to a thickness of 0.1 nm to 500 nm.

24. The method of claim 11, wherein the second electrode layer is formed in a thickness of approximately 0.1 nm to 500 nm.

25. The method of claim 11, wherein the third electrode layer is formed in a thickness of approximately 10 nm to 1000 nm.
